(19) United States
(12) Patent Application Publication
(10) Pub. No.: US 2023/0266570 A1
(43) Pub. Date: Aug. 24, 2023

(54) Lens Module

(71) Applicants: Sintai Optical (Shenzhen) Co., Ltd., ShenZhen City (CN); Asia Optical Co., Inc., Taichung (TW)

(72) Inventor: Kazutaka Goami, Taichung (TW)

(21) Appl. No.: 18/145,085

(22) Filed: Dec. 22, 2022

(30) Foreign Application Priority Data
Feb. 18, 2022 (TW) 111201709
Jun. 2, 2022 (TW) 111120703

(51) Int. Cl. G02B 15/14; G02B 7/08; H04N 23/54; H04N 23/55; H05K 1/18

(52) U.S. Cl. CPC G02B 15/144; G02B 7/08; H04N 23/54; H04N 23/55; H05K 1/189

(57) ABSTRACT

A lens module includes a base, a movable lens group, a magnet portion and a coil portion. The movable lens group is movable in a first direction and has an optical axis in parallel to the first direction. The magnet portion is disposed on one of the base and the movable lens group. The coil portion is disposed on the other of the base and the movable lens group and is disposed corresponding to the magnet portion.

### BACKGROUND OF THE INVENTION

### Field of the Invention

The invention relates to the optical field, and more particularly to a lens module.

### Description of the Related Art

Generally, a lens module includes an aperture stop and a plurality of lens groups. Some of the lens groups are required to move during auto focusing operation, zooming operation or optical image stabilization (OIS) operation. However, a collision between the moving lens groups and other elements (e.g. the aperture stop, other lens groups and so on) may occur. Such a collision may generate abnormal sound (i.e. noise) and even may cause damage to the elements. Further, at least one driving device is included in the lens module for driving the movable lens groups. When the coils of the driving device are installed on the base of the lens module, it is limited by the position accuracy requirements and the assembly line, which makes the installation work difficult and the assembly quality unstable. In order to supply power to the coils, soldering the conducting lines of the coils to the flexible circuit board is required, which, however, is tricky.

### BRIEF SUMMARY OF THE INVENTION

The invention provides a solution to address the described drawbacks, wherein the lens module of the invention is capable of reducing noise during operation.

The lens module in accordance with an exemplary embodiment of the invention includes a base, a movable lens group, a magnet portion and a coil portion. The movable lens group is movable in a first direction and has an optical axis in parallel to the first direction. The magnet portion is disposed on one of the base and the movable lens group. The coil portion is disposed on the other of the base and the movable lens group and is disposed corresponding to the magnet portion.

In another exemplary embodiment, the coil portion consists of two coils, the magnet portion includes three magnets arranged in the first direction, the magnets are monopole magnets with N-pole and S-pole alternatively arranged in the first direction.

In yet another exemplary embodiment, the lens module further includes a magnetic substance with the magnets adhered thereto.

In another exemplary embodiment, the magnets satisfy at least one of following conditions: w(p)≥w(m), w(c)=(1.5+n)w(p), n=0, 1, 2 . . . , w(ec−ec)=w(p), and 1.0 mm≤w(m)≤1.35 mm, where w(p) is a magnet pitch of each of the magnets, w(m) is a width of each of the monopole magnets, w(c) is a distance between centers of the coils, and w(ec−ec) is a distance between centers of winding width of each of the coils.

In yet another exemplary embodiment, the coils include a first coil and a second coil, and electric currents applied to the first coil and the second coil satisfy I_c1=Icom·

$$sin ( 360 ° \cdot \frac{P}{2 w ( m )} + θ ) and I\_c2 = Icom \cdot sin ( 360 ° \cdot \frac{P}{2 w ( m )} + ( θ - 90 ° ) )$$

where I_c1 is the electric current applied to the first coil, I_c2 is the electric current applied to the second coil, Icom is a common current of the first coil and the second coil, P is a position of the coil portion, and θ is a phase shift amount when P=0.

In another exemplary embodiment, the coil portion consists of two coils arranged in the first direction, the magnet portion includes a multi-pole magnet with N-pole and S-pole alternatively arranged in the first direction.

In yet another exemplary embodiment, the lens module further includes a position magnet, a sensor, and a driving unit. The position magnet is disposed on the base. The sensor is disposed on the movable lens group to sense a position or a moving distance of the position magnet. The driving unit receives a signal of the position or the moving distance of the position magnet from the sensor and correspondingly adjusts an electric current applied to the coil portion.

In another exemplary embodiment, the lens module further includes a first lens group and a buffer unit. The first lens group is fixedly disposed in the base. The buffer unit is disposed in the base. The movable lens group is a second lens group which is disposed in the base, and the first lens group and the second lens group are arranged along the optical axis. The buffer unit contacts with the first lens group when the second lens group moving towards the first lens group is stopped.

In yet another exemplary embodiment, the buffer unit is disposed on at least one of the first lens group, the second lens group and the base.

In another exemplary embodiment, the lens module further includes an aperture stop disposed in the base. The buffer unit is disposed on the second lens group and includes a first propping portion and a second propping portion. The first propping portion is extended towards the first lens group. The second propping portion is extended towards the aperture stop. The first propping portion is propped against the first lens group when the second lens group is moved towards the first lens group and is stopped. The second propping portion is propped against the aperture stop when the second lens group is moved towards the aperture stop and is stopped.

In yet another exemplary embodiment, material of the buffer unit includes polyoxymethylene or the buffer unit has polyoxymethylene provided thereon.

In another exemplary embodiment, the lens module further includes buffering material. The buffer material is disposed on the first lens group or the second lens group. The buffer unit contacts with the buffering material when the second lens group is moved towards the first lens group and is stopped.

In yet another exemplary embodiment, the lens module further includes a driving device for driving the second lens group to move, wherein the driving device includes a magnet portion disposed on the second lens group and a coil portion disposed in the base and corresponding to the magnet portion.

In another exemplary embodiment, the coil portion includes a plurality of coils and a flexible circuit board, the flexible circuit board supplies power to the coils to generate a magnetic field that acts on the magnet portion, and the second lens group is driven to move along the optical axis when the coil portion is supplied with power to generate a magnetic force that acts on the magnet portion.

In yet another exemplary embodiment, the coil portion further includes a carrier and a plurality of columnar protrusions, the carrier is substantially planar, the columnar protrusions are disposed on the carrier to fix the coils, and the flexible circuit board is bent and is connected to the carrier.

In another exemplary embodiment, the lens module further includes a position sensor. The magnet portion is disposed on the second lens group. The coil portion is disposed on the base. The flexible circuit board includes an extending portion extended towards the second lens group. The position sensor is disposed on the extending portion. The flexible circuit board includes an electrically connecting portion extended in a direction away from the second lens group and configured to connect to an external power supply.

In yet another exemplary embodiment, the lens module further includes a third lens group, a fourth lens group and an aperture stop, wherein the first lens group and the fourth lens group are fixed, the second lens group and the third lens group are movable, and the aperture stop is fixedly disposed in the base and between the first lens group and the fourth lens group.

In another exemplary embodiment, the lens module further includes a third lens group, a fourth lens group and an aperture stop, wherein the first lens group and the fourth lens group are movable, the second lens group and the third lens group are fixed, and the aperture stop is fixedly disposed in the base and between the first lens group and the fourth lens group.

In yet another exemplary embodiment, the lens module further includes a third lens group, a fourth lens group and an aperture stop. One of the first lens group and the fourth lens group is movable and the other of the first lens group and the fourth lens group is fixed. One of the second lens group and the third lens group is movable and the other of the second lens group and the third lens group is fixed. The aperture stop is fixedly disposed in the base and between the first lens group and the fourth lens group.

### BRIEF DESCRIPTION OF THE DRAWINGS

FIG. 1 is a schematic view showing the structure of a lens module in accordance with the first embodiment of the invention.

FIG. 2 is another schematic view showing the structure of the lens module at a different view angle in accordance with the first embodiment of the invention.

FIG. 3 is a schematic view showing the structure of one of lens groups of the lens module of FIGS. 1 and 2.

FIG. 4 is another schematic view showing the structure of one of lens groups of the lens module of FIGS. 1 and 2 at a different view angle.

FIG. 5 is yet another schematic view showing the structure of one of lens groups of the lens module of FIGS. 1 and 2 at another different view angle.

FIG. 6 is a schematic view showing the structure of a base of the lens module of FIGS. 1 and 2.

FIG. 7 is another schematic view showing the structure of the base of the lens module of FIGS. 1 and 2 at a different view angle.

FIG. 8 is a schematic view showing the structure of the lens module in accordance with a second embodiment of the invention.

FIG. 9 is another schematic view showing the structure of the lens module at a different view angle in accordance with the second embodiment of the invention.

FIG. 10 is a schematic view showing the structure of one of lens groups of the lens module of FIGS. 8 and 9.

FIG. 11 is another schematic view showing the structure of one of lens groups of the lens module of FIGS. 8 and 9 at a different view angle.

FIG. 12 is a schematic view showing the structure of a base of the lens module of FIGS. 8 and 9.

FIG. 13 is a front view of a coil portion and a magnet portion of the lens module in accordance with the first embodiment of the invention.

FIG. 14 is a bottom view of the coil portion and the magnet portion of the lens module in accordance with the first embodiment of the invention.

FIG. 15 is a schematic view showing the structure in which the magnet portion is attached to a magnetic substance in accordance with the first embodiment of the invention.

FIG. 16 is another schematic view showing the structure at a different view angle in which the magnet portion is attached to the magnetic substance in accordance with the first embodiment of the invention.

FIG. 17 is a schematic view showing the structure in which the magnet portion is a multi-pole magnet in accordance with the first embodiment of the invention.

FIG. 18 is a front view of the magnet portion of FIG. 17.

FIG. 19 depicts how the coil portion of the lens module of the first embodiment of the invention sustains a force in accordance with Fleming's Left Hand Rule.

FIG. 20 depicts movement of the coil portion of the lens module and the corresponding current distribution rates in accordance with the first embodiment of the invention.

FIG. 21 is a block diagram of the lens module in accordance with the first embodiment of the invention.

FIG. 22 depicts where the magnetic flux density is measured for the magnet portion in the invention.

FIG. 23 is a top view of the coil portion and the magnet portion of FIG. 22.

FIG. 24 shows the magnetic flux densities measured in different positions of magnets of different widths.

FIG. 25 shows tolerance of 45° point for the magnetic flux density measured in different positions of a magnet of width w(m)=1.2 mm.

FIG. 26 depicts the pulsation value associated with the position of the coil force is equivalent to ±3%.

FIG. 27 shows the correlation between the tolerance of 45° point and the magnet width.

FIG. 28 shows the correlation between the magnetic flux density (T) and the tolerance of 45° point (%) measured in different positions of the magnet during movement of the coil when the magnet width is 1.2 mm.

FIG. 29 shows the correlation between the magnetic flux density (T) and the tolerance of 45° point (%) measured in different positions of the magnet during movement of the coil after that in FIG. 28.

FIG. 30 shows the correlation between the magnetic flux density (T) and the tolerance of 45° point (%) measured in different positions of the magnet during movement of the coil after that in FIG. 29.

FIG. 31 shows the correlation between the magnetic flux density (T) and the tolerance of 45° point (%) measured in different positions of the magnet during movement of the coil after that in FIG. 30.

FIG. 32 is a schematic view showing the structure of a lens module in accordance with a third embodiment of the invention.

FIG. 33 is a schematic view showing part structure of the lens module in accordance with the third embodiment of the invention.

FIG. 34 is a perspective view of a coil portion in accordance with the third embodiment of the invention.

FIG. 35 is another perspective view of a coil portion observed at a different angle in accordance with the third embodiment of the invention.

FIG. 36 depicts the coil portion installed on the base during assembly of the lens module in accordance with the third embodiment of the invention.

### DETAILED DESCRIPTION OF THE INVENTION

The purposes, technical solutions and merits of the invention can be more fully understood by reading the subsequent detailed description and embodiments with references made to the accompanying drawings. However, it is understood that the subsequent detailed description and embodiments are only used for explaining the invention. The invention is not limited thereto.

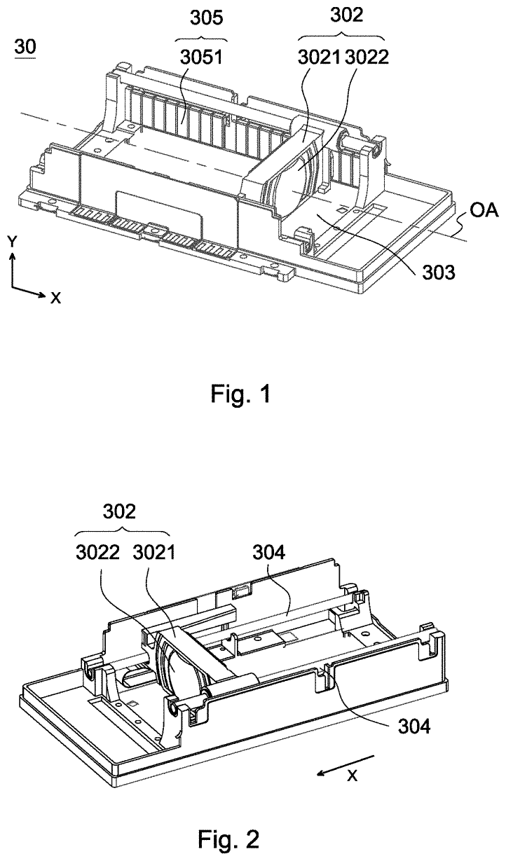

Referring to FIGS. 1-2, the lens module 30 of the invention includes a base 303. Plural lens groups are provided on the base 303 and arranged in a first direction X and have an optical axis OA extending in the first direction X, wherein one or more lens groups are movable and the other lens group(s) is stationary. In FIGS. 1 and 2, only one movable lens group 302 is shown. However, this is only an example for a purpose of descriptions and the invention is not limited thereto. The lens group 302 includes a lens frame 3021 and one or more lenses 3022 disposed in the lens frame 3021.

All the lens groups are supported by a guide unit. In this embodiment, the guide unit includes two guide rods 304. The two guide rods 304 are disposed at both sides of the lens groups and extend in the first direction X for supporting the lens groups. It is understood that the number of the guide rods may be less than or more than two. Further, the guide unit may include a guide rail(s), a guide groove(s) and/or another similar structure that is substituted for the guide rods 304 to support the lens groups.

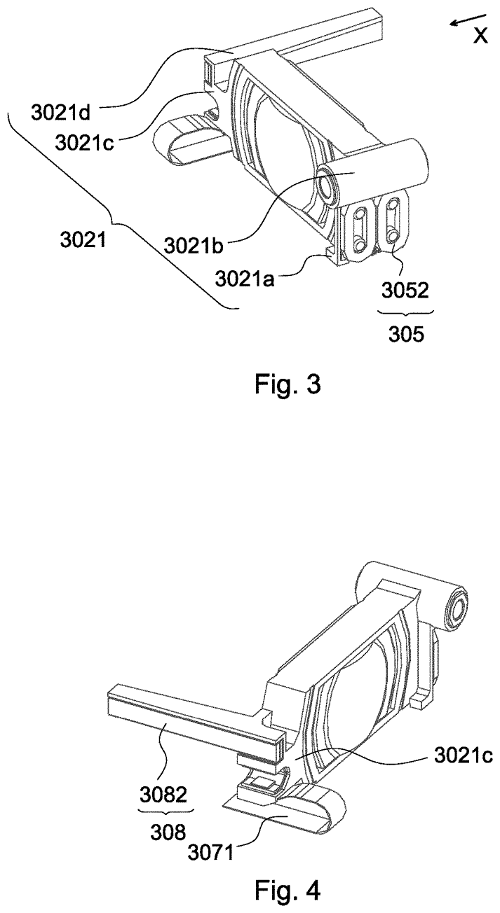

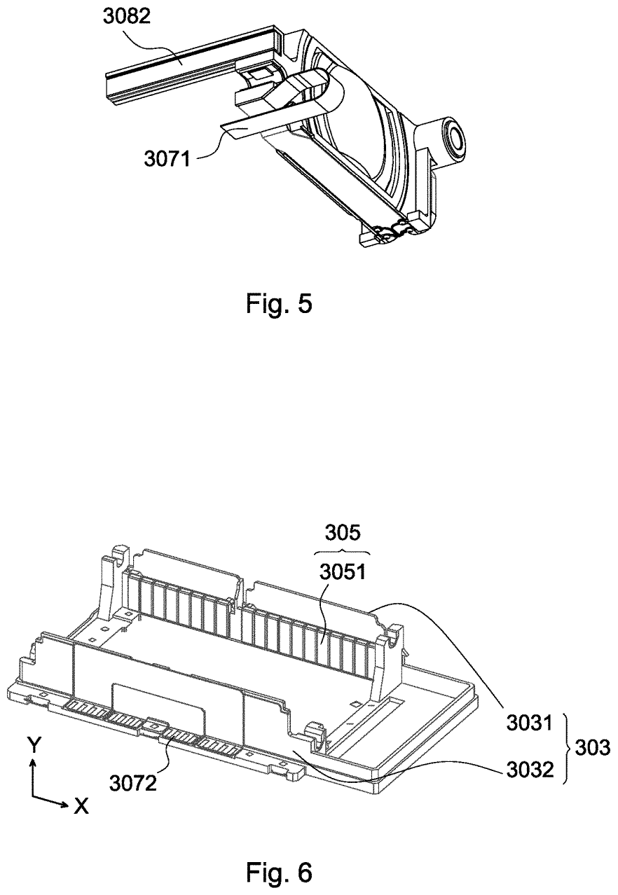

Referring to FIGS. 3, 4 and 5, the lens frame 3021 has a side on which a support portion 3021a and a sleeve portion 3021b are disposed, and another side on which a protrusion 3021c and a holding portion 3021d are disposed. One of the guide rods 304 is penetrated through the sleeve portion 3021b for supporting the lens group 302 and guiding the lens group 302 to slide in the first direction X. The support portion 3021a is configured to support the coil portion 3052. The coil portion 3052 is fixed to the support portion 3021a by twining, hanging, gluing or in other fixing ways. The holding portion 3021d extends in the first direction X to fix the position magnet 3082. The protrusion 3021c has a C-shaped cross section and is open laterally for containing the other guide rod 304. A flexible circuit board 3071 is disposed under the protrusion 3021c and is electrically connected to the coil portion 3052.

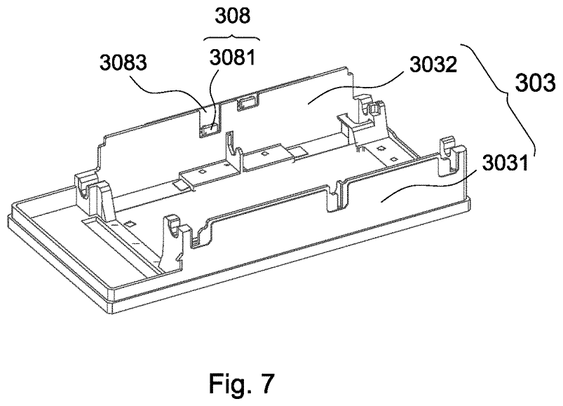

Referring to FIGS. 6 and 7, the base 303 includes two side walls 3031, 3032 extending in a second direction Y wherein the second direction Y is perpendicular to the first direction X. A magnet portion 3051 is disposed on one side wall 3031, and a circuit board 3083 is disposed on the other side wall 3032. A sensor (e.g. Hall sensor) 3081 is disposed on the circuit board 3083. A flexible circuit board 3071 is electrically connected to the circuit board 3083. An electrically connecting portion 3072 is extended outwardly from the side wall 3032 for electrically connecting to an external power supply, thereby introducing an electric current into the lens module 30. Specifically, power is supplied to the sensor 3081 disposed on the circuit board 3083 and is also supplied to the coil portion 3052 disposed on the lens frame 3021 through the flexible circuit board 3071.

In this embodiment, the coil portion 3052 is disposed on the lens group 302. The magnet portion 3051 is disposed on the base 303. The coil portion 3052 and the magnet portion 3051 constitute a driving unit 305 of the lens module 30. In operation, the magnet portion 3051 creates a magnetic field. Power is supplied to the lens module 30. The coil portion 3052 sustains an electromagnetic force to move and drives the lens group 302 to move in the first direction X. Further, the sensor 3081 on the side wall 3032 is disposed corresponding to the position magnet 3082 on the lens frame 3021. The sensor 3081 and the position magnet 3082 constitute a position sensing unit 308. When the lens group 302 is moved, the sensor 3081 is able to sense the position and moving distance of the position magnet 3082 and the electric current applied to the coil portion 3052 is adjusted accordingly, thereby changing the electromagnetic force acting on the coil portion 3052. The detail will be described later.

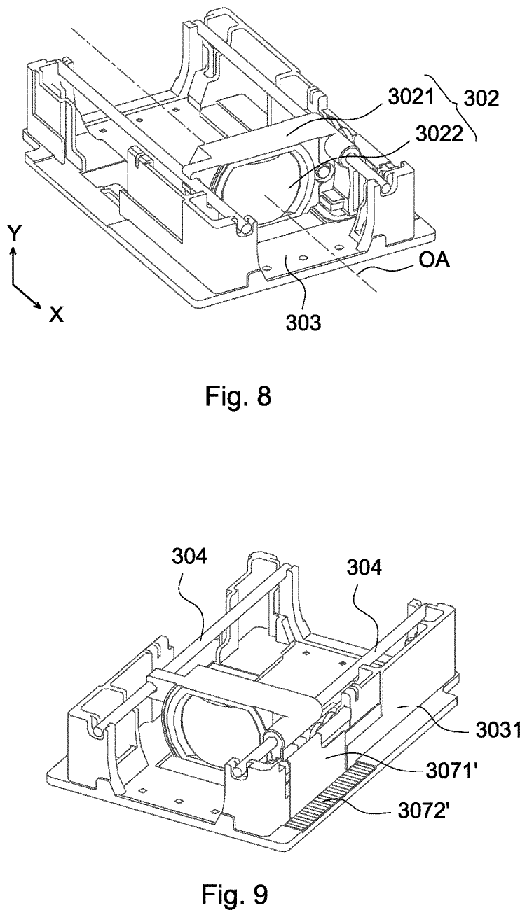

It is understood that the positions of the coil portion 3052 and the magnet portion 3051 can be exchanged. That is, the coil portion 3052 can be rearranged to be disposed on the base 303 and the magnet portion 3051 can be rearranged to be disposed on the lens group 302. Referring to FIGS. 8-12, FIGS. 8-12 depict a lens module in accordance with a second embodiment of the invention, wherein the elements same as those of the first embodiment are provided with the same reference numerals and the descriptions thereof are omitted. As shown, the coil portion 3052′ is disposed on the side wall 3031 of the base 303 and the magnet portion 3051′ is disposed on the lens frame 3021′ of the lens group 302. The coil portion 3052′ and the magnet portion 3051′ constitute a driving unit 305 to drive the lens group 302.

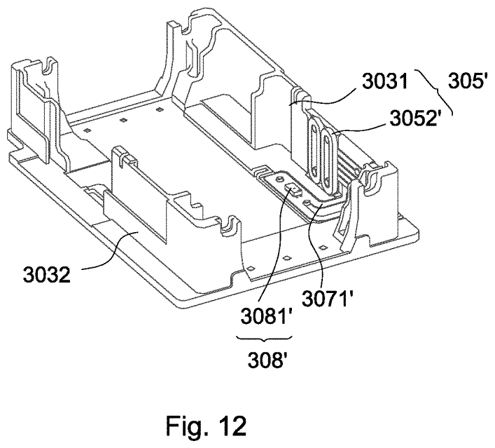

As shown in FIG. 12, an electrically connecting portion 3072′ is extended outwardly from the side wall 3031 of the base 303. A flexible circuit board 3071′ is disposed on the side wall 3031 of the base 303. Specifically, the flexible circuit board 3071′ is bent and extended over the side wall 3031 of the base 303 and is electrically connected to the electrically connecting portion 3072′ at the outside of the side wall 3031 of the base 303 (FIG. 9). Further, the flexible circuit board 3071′ is extended to be substantially L-shaped at the inside of the side wall 3031 (FIG. 12). The sensor (Hall sensor) 3081′ is disposed on the flexible circuit board 3071′. The external power supply (not shown) can supply power to the sensor 3081′ and the coil portion 3052′ through the electrically connecting portion 3072′ and the flexible circuit board 3071′.

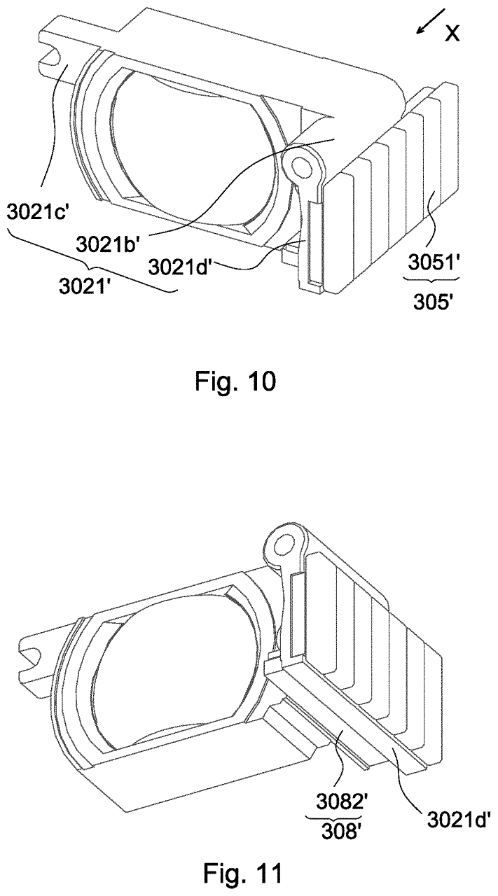

Referring to FIGS. 10 and 11, the lens frame 3021′ has a side on which a sleeve portion 3021b′ and a holding portion 3021d′ are disposed, and another side on which a protrusion 3021c′ is disposed. Two guide rods 304 disposed in parallel are respectively penetrated through the sleeve portion 3021b′ and the protrusion 3021c′. The holding portion 3021d′ extends in the first direction X for fixing the magnet portion 3051′ so that the magnet portion 3051′ can be disposed corresponding to the coil portion 3052′. A position magnet 3082′ is fixed onto the holding portion 3021d′ and corresponds to the sensor (Hall sensor) 3081′. The sensor 3081′ and the position magnet 3082′ constitute a position sensing unit 308′. It is worth noting that the magnet portion 3051′ and the position magnet 3082′ are disposed on opposite sides of the holding portion 3021d′.

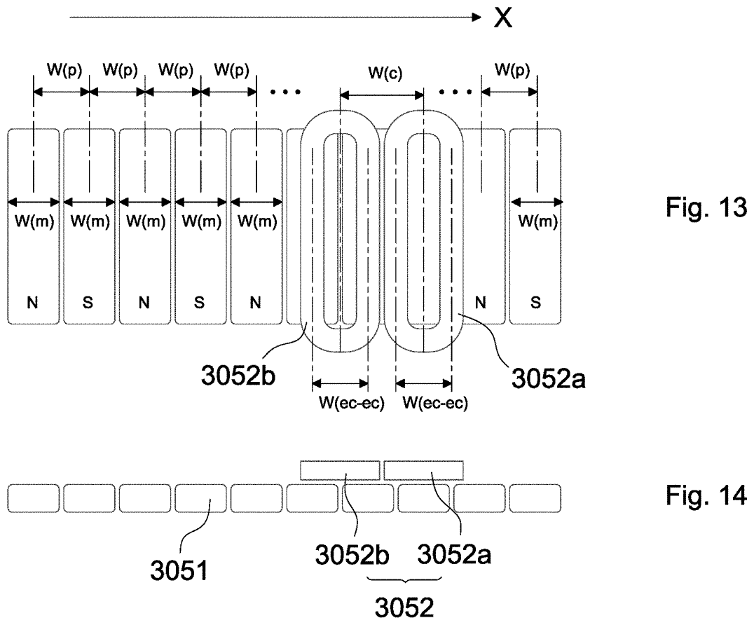

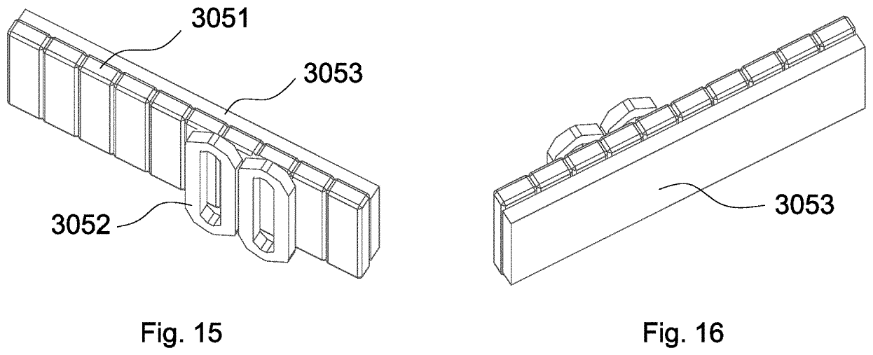

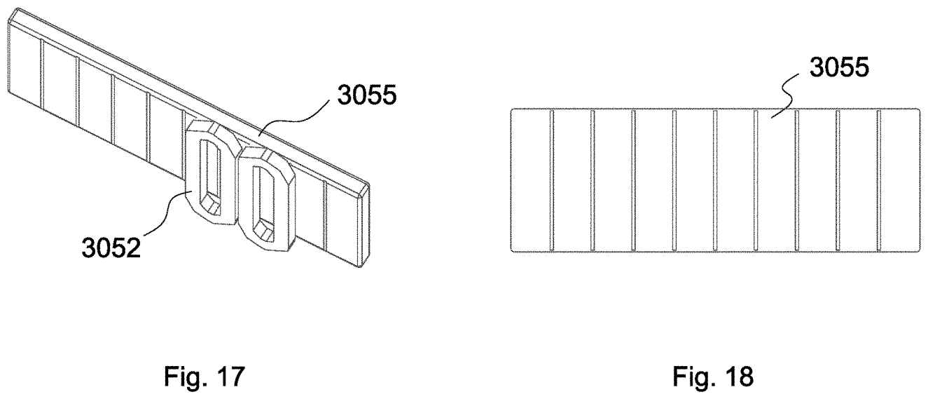

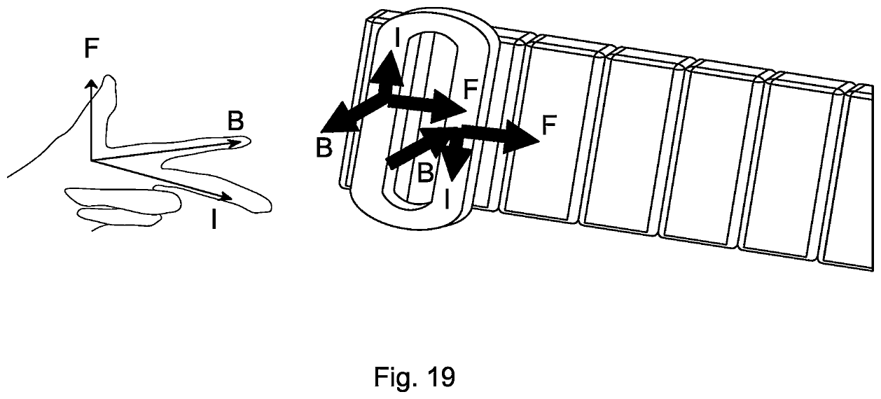

The coil portion and the magnet portion are described in detail in the following, wherein the coil portion 3052 and the magnet portion 3051 of the first embodiment are taken as a representative for descriptions while the coil portion 3052′ and the magnet portion 3051′ of the second embodiment are not described because of the similarity. Referring to FIGS. 13 and 14, the coil portion 3052 includes a first coil 3052a and a second coil 3052b. The magnet portion 3051 includes at least three magnets. The magnets, the first coil 3052a and the second coil 3052b are arranged in the first direction X that is the direction the lens group 302 is driven to move in. The magnets may be monopole magnets. A so-called monopole magnet still has two magnetic poles. However, only one magnetic pole is used. The monopole magnets of the invention are arranged in accordance with the order of N-pole, S-pole, N-pole, S-pole, N-pole . . . (or S-pole, N-pole, S-pole, N-pole, S-pole . . . ) wherein N-pole and S-pole are alternately arranged. To improve the magnetic performance and to facilitate the assembly, the magnets of the invention can be adhered to a magnetic substance 3053. As shown in FIGS. 15 and 16, the magnetic substance 3053 may be a magnetic yoke made of SPCC cold rolled steel. In the invention, a plurality of monopole magnets can be replaced with a multi-pole magnet shown in FIGS. 17 and 18.

Referring to FIG. 13 again, in the invention, at least one of following conditions is satisfied:

w(p) [symbol] w(m) (1)

w(c)=(1.5+n)w(p),n=0,1,2 (2)

w(ec−ec)=w(p) (3)

where w(m) is a width of one monopole magnet, w(p) is a magnet pitch that is the distance between the centers of each two monopole magnets or the distance between the boundary lines of each magnetic pole of a multi-pole magnet, w(c) is a distance between the centers of two coils, and w(ec-ec) is a distance between centers of winding width of the first coil 3052a (or the second coil 3052b), or the distance between the centers of the first coil 3052a and the second coil 3052b.

Accordingly, the monopole magnets have gaps therebetween when w(p)>w(m). A better magnetic circuit efficiency can be obtained when w(p)=w(m). It is beneficial to control the relative position between the coil and the magnet when w(m) is ranged from 1.00 mm to 1.35 mm. It is preferred that w(m)=1.2 mm. The dimensions of the driving unit 305 of the lens module 30 can be minimized when n=0.

It is worth noting that any practical errors related to accuracy of dimensions of elements and accuracy of assembly of elements are not considered in the above design.

In order to control the relative position between the coil and the magnet, the relationship between the current polarity and the current distribution rate are necessarily considered and the electric current applied to the coil portion is determined accordingly. No matter where the lens group is, the electromagnetic forces for driving the lens group are required to be stable and the control is required to be seamless and stable. In the invention, the current polarity and the current distribution rate are designed in form of sine waves, with the position of the coil portion taken as a variable. Further, the phase difference between the two coils is 90°. Accordingly, the electric currents applied to the first coil and the second coil in the invention are as follows.

$$\begin{matrix}I\_c1 = Icom \cdot sin ( 360 ° \cdot \frac{P}{2 w ( m )} + θ ) & ( 4 ) \\ I\_c2 = Icom \cdot sin ( 360 ° \cdot \frac{P}{2 w ( m )} + ( θ + 90 ° ) ) & ( 5 )\end{matrix}$$

where I_c1 is the electric current applied to the first coil 3052a, I_c2 is the electric current applied to the second coil 3052b, Icom is the common current of the first coil and the second coil, P is the position of the coil portion, and θ is the amount of phase shift when P=0 that depends from the relative position between the coil portion and the magnet portion.

In the above conditions (4) and (5), the common current Icom is necessarily determined under the consideration that the movement of the lens group is under control and the lens group under the gravity and the external disturbances (e.g. shocks) can be still kept at the desired position.

When the amount of phase shift θ=0, the above conditions (4) and (5) can be rewritten as:

I_c1=Icom·α1 (6)

I_c1=Icom·α2 (7)

where α1, α2 are the current distribution rates and can be expressed as:

$$\begin{matrix}α1 = sin ( 360 ° \cdot \frac{P}{2 w ( m )} + θ ) & ( 8 ) \\ α2 = sin ( 360 ° \cdot \frac{P}{2 w ( m )} + ( θ + 90 ° ) ) & ( 9 )\end{matrix}$$

FIG. 19 depicts Fleming's Left Hand Rule, wherein the index finger indicates the direction of the magnetic field, the middle finger indicates the direction of the electric current, and the thumb indicates the direction of the force. If a coil is placed in a magnetic field B created by a magnet and an electric current I passes through the coil, then the coil will sustain a force F and F=I×B where F, I and B are vectors and × is cross product.

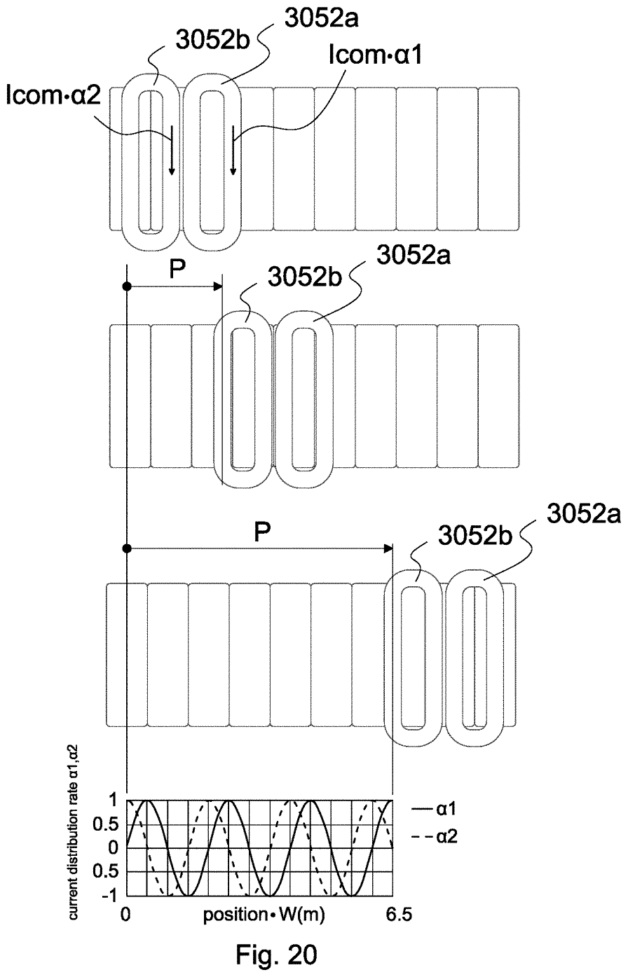

Referring to FIG. 20, when an electric current Icom·α1 is applied to the first coil 3052a and an electric current Icom·α2 is applied to the second coil 3052b, the first coil 3052a and the second coil 3052b sustain a force F and begin to move toward the right from the position P=0. FIG. 20 also shows the variation of the current distribution rates α1 and α2 corresponding to the first coil 3052a and the second coil 3052b in different positions.

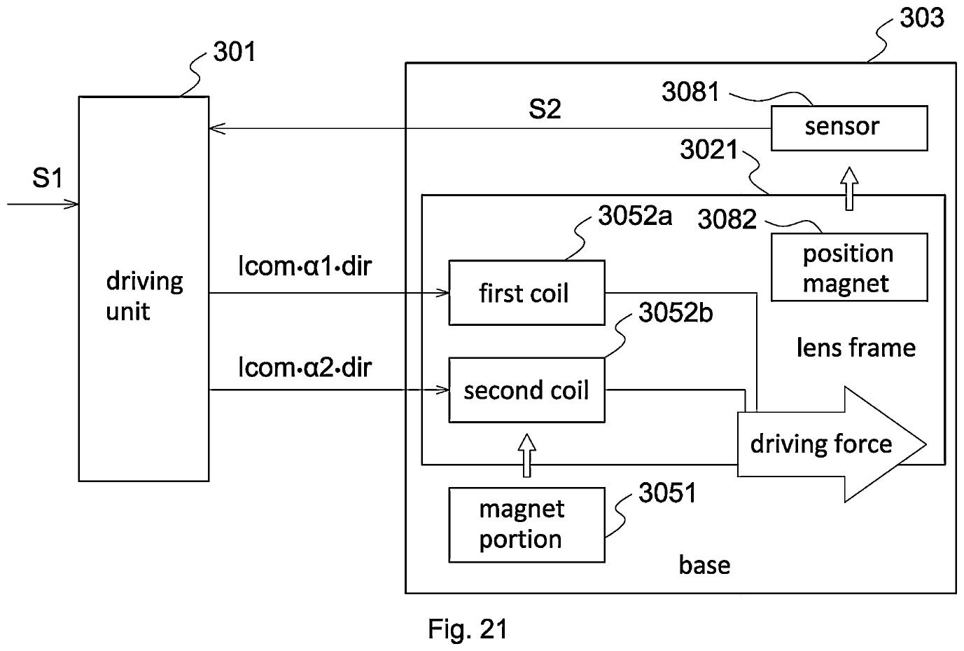

Referring to FIG. 21, FIG. 21 is a block diagram of the lens module in accordance with the first embodiment of the invention. As shown, when receiving a zoom ratio signal or a predetermined position signal S1, the driving unit (e.g. a driving chip) correspondingly outputs the electric currents Icom·α1·dir and Icom·α2·dir to the first coil 3052a and the second coil 3052b wherein dir is a coefficient for the moving direction. Specifically, dir is +1 when the movement is in the first direction X, and dir is −1 when the movement is in a direction opposite to the first direction X. Then, as shown in FIGS. 19 and 20, the first coil 3052a and the second coil 3052b sustain forces and begin to move, and the lens frame 3021 of the lens group is moved along with the first coil 3052a and the second coil 3052b in the first direction X or in a direction opposite to the first direction X. The sensor 3081 senses the position or moving distance of the position magnet 3082 disposed on the lens frame 3021 and outputs a real-time position signal S2 to the driving unit 301 so that the driving unit 301 can adjust the electric currents Icom·α1·dir and Icom·α2·dir output to the first coil 3052a and the second coil 3052b. By continuous adjustment of the electric currents, the lens frame 3021 of the lens group can be moved to the predetermined position accurately.

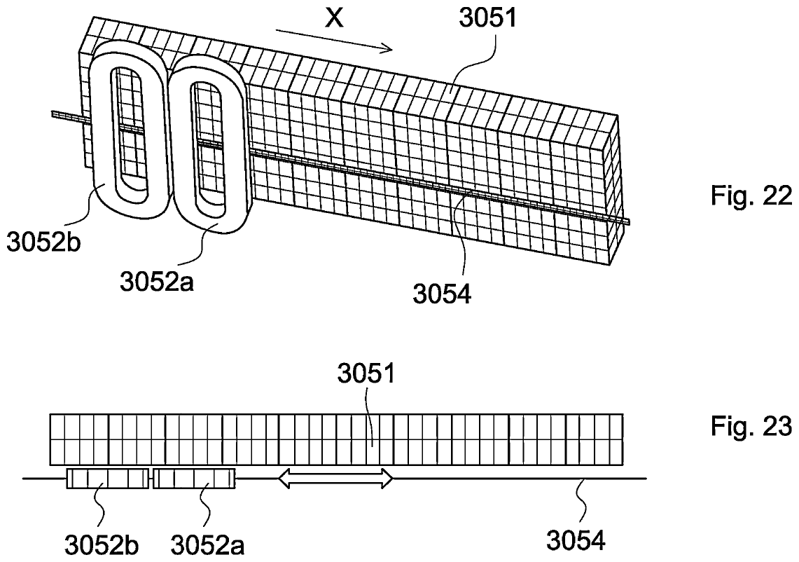

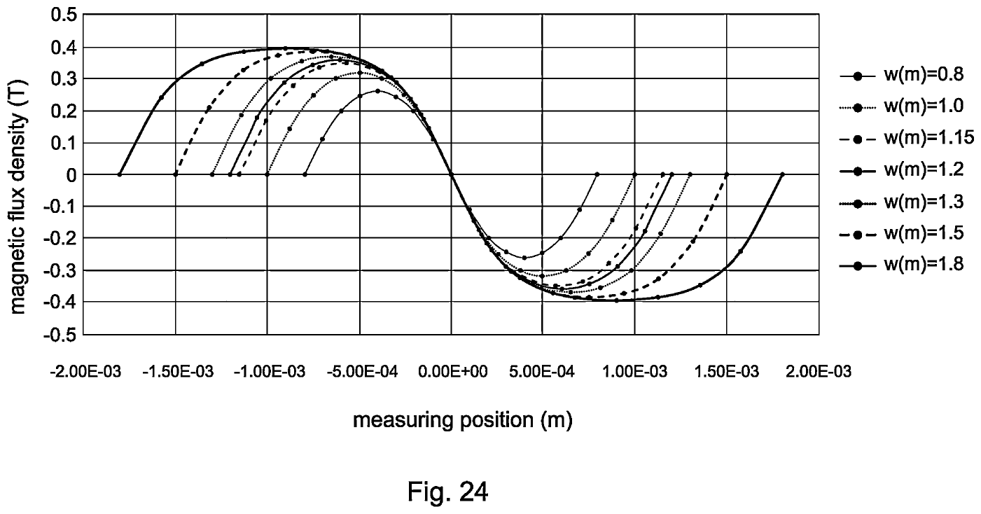

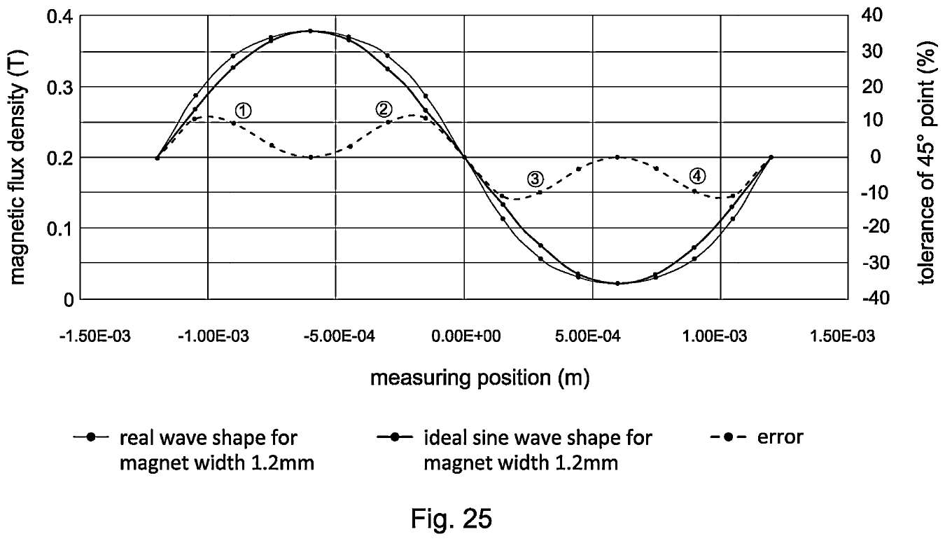

Referring to FIGS. 22 and 23, in the invention, the magnetic flux density is measured at the middle of the magnet portion 3051. All the measuring points are arranged in a straight line 3054, and the straight line 3054 is parallel to the first direction X in which the first coil 3052a and the second coil 3052b are moved. FIG. 24 shows the magnetic flux densities measured in different positions of magnets of different widths, wherein the magnetic flux densities for magnets of seven different widths w(m)=0.8 mm, 1.0 mm, 1.15 mm, 1.2 mm, 1.3 mm, 1.5 mm, 1.8 mm are simultaneously shown for easy comparison. In the invention, the design for the magnetic circuit is that the fluctuation of the magnetic flux density is as close as possible to a sine wave and the maximum value of the magnetic flux density is large. After study, it is found that the smaller the magnet width, the higher the reproducibility of a sine wave. To assess the reproducibility of sine waves, “45° point error” is defined. FIG. 25 show the magnetic flux density measured in different positions of a magnet of width w(m)=1.2 mm, wherein the ideal sine wave and the real wave are compared at four points \textcircled{1}, \textcircled{2}, \textcircled{3}, \textcircled{4}. It is required that all the errors at the four points \textcircled{1}, \textcircled{2}, \textcircled{3}, \textcircled{4} are within the tolerance of 45° point, where the tolerance of 45° point=((the real value at the measuring point)−(the ideal value at the measuring point))/(the real peak value). In the invention, the tolerance of 45° point is set to 9.7%. It can be seen from FIG. that all the errors at the four points \textcircled{1}, \textcircled{2}, \textcircled{3}, \textcircled{4} are within 9.7%. Therefore, the wave shape of the magnetic flux density of the magnet of width w(m)=1.2 mm is considered close to a sine wave.

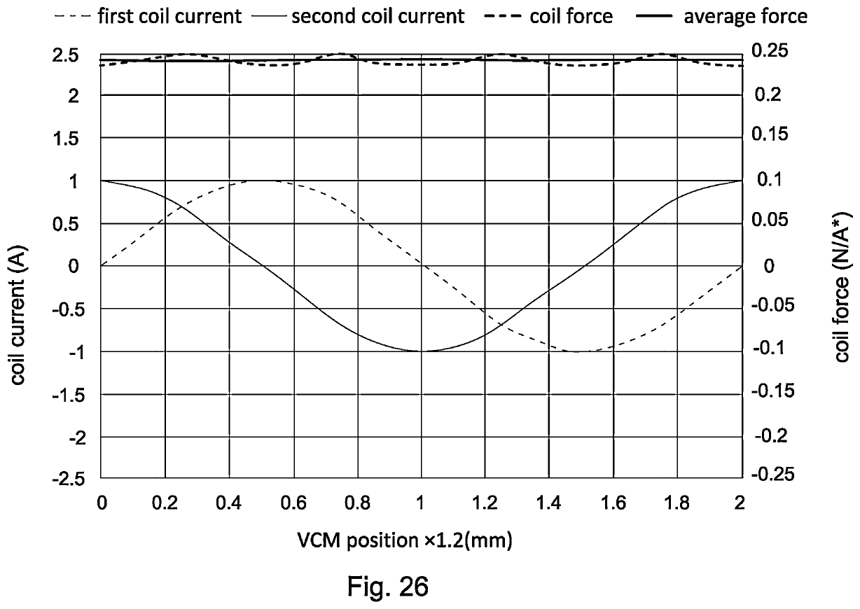

Further, the pulsation value associated with the position of the coil force is equivalent to ±3%. As shown in FIG. 26, the pulsation value is ±3% of the average force. When the driving current applied to the coil is in a sine wave form, there is a ¼ correlation between the value of tolerance and the fluctuation value of the coil force. In the invention, therefore, the index of tolerance is set to at most 12% (=3%×4).

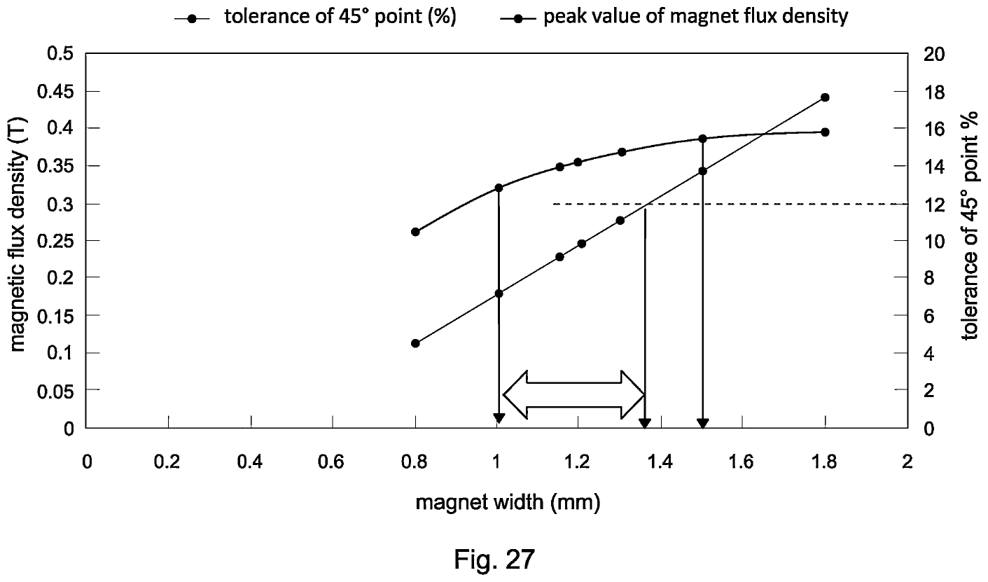

It is worth noting that the magnetic flux density drops sharply when the magnet width is less than a certain value. As shown in FIG. 27, the magnetic flux density drops sharply when the magnet width is less than 1.0 mm. However, when the magnet width is increased to another value, the maximum magnetic flux density is almost saturated. It is therefore understood that there are restrictions to the magnet width because of the deterioration and increase in the reproducibility of the sine wave. It can be seen from FIG. 27 that the magnet width cannot exceed 1.5 mm. Also from FIG. 27, the magnet width is necessarily less than or equal to 1.35 mm in case the tolerance value is at most 12%. Thus, the condition 1.0 mm≤w(m)≤1.35 mm is required in the invention.

Tables 1-7 show the magnet width w(m) and the corresponding current distribution rates α1, α2 of the invention in detail.

TABLE 1
0

| w(m) | 0 | 0.125 | 0.25 | 0.375 | 0.5 | 0.625 | 0.75 | 0.875 |
|---|---|---|---|---|---|---|---|---|
| α1 | 0.000 | 0.383 | 0.707 | 0.924 | 1.000 | 0.924 | 0.707 | 0.383 |
| α2 | 1.000 | 0.924 | 0.707 | 0.383 | 0.000 | −0.383 | −0.707 | −0.924 |

TABLE 2
w(m)

| w(m) | 1 | 1.125 | 1.25 | 1.375 | 1.5 | 1.625 | 1.75 | 1.875 |
|---|---|---|---|---|---|---|---|---|
| α1 | 0.000 | −0.383 | −0.707 | −0.924 | −1.000 | −0.924 | −0.707 | −0.383 |
| α2 | −1.000 | −0.924 | −0.707 | −0.383 | 0.000 | 0.383 | 0.707 | 0.924 |

TABLE 3
2w(m)

| w(m) | 2 | 2.125 | 2.25 | 2.375 | 2.5 | 2.625 | 2.75 | 2.875 |
|---|---|---|---|---|---|---|---|---|
| α1 | 0.000 | 0.383 | 0.707 | 0.924 | 1.000 | 0.924 | 0.707 | 0.383 |
| α2 | 1.000 | 0.924 | 0.707 | 0.383 | 0.000 | −0.383 | −0.707 | −0.924 |

TABLE 4
3w(m)

| w(m) | 3 | 3.125 | 3.25 | 3.375 | 3.5 | 3.625 | 3.75 | 3.875 |
|---|---|---|---|---|---|---|---|---|
| α1 | 0.000 | −0.383 | −0.707 | −0.924 | −1.000 | −0.924 | −0.707 | −0.383 |
| α2 | −1.000 | −0.924 | −0.707 | −0.383 | 0.000 | 0.383 | 0.707 | 0.924 |

TABLE 5
4w(m)

| w(m) | 4 | 4.125 | 4.25 | 4.375 | 4.5 | 4.625 | 4.75 | 4.875 |
|---|---|---|---|---|---|---|---|---|
| α1 | 0.000 | 0.383 | 0.707 | 0.924 | 1.000 | 0.924 | 0.707 | 0.383 |
| α2 | 1.000 | 0.924 | 0.707 | 0.383 | 0.000 | −0.383 | −0.707 | −0.924 |

TABLE 6
5w(m)

| w(m) | 5 | 5.125 | 5.25 | 5.375 | 5.5 | 5.625 | 5.75 | 5.875 |
|---|---|---|---|---|---|---|---|---|
| α1 | 0.000 | −0.383 | −0.707 | −0.924 | −1.000 | −0.924 | −0.707 | −0.383 |
| α2 | −1.000 | −0.924 | −0.707 | −0.383 | 0.000 | 0.383 | 0.707 | 0.924 |

TABLE 7
6w(m)

| w(m) | 6 | 6.125 | 6.25 | 6.375 | 6.5 |
|---|---|---|---|---|---|
| α1 | 0.000 | 0.383 | 0.707 | 0.924 | 1.000 |
| α2 | 1.000 | 0.924 | 0.707 | 0.383 | 0.000 |

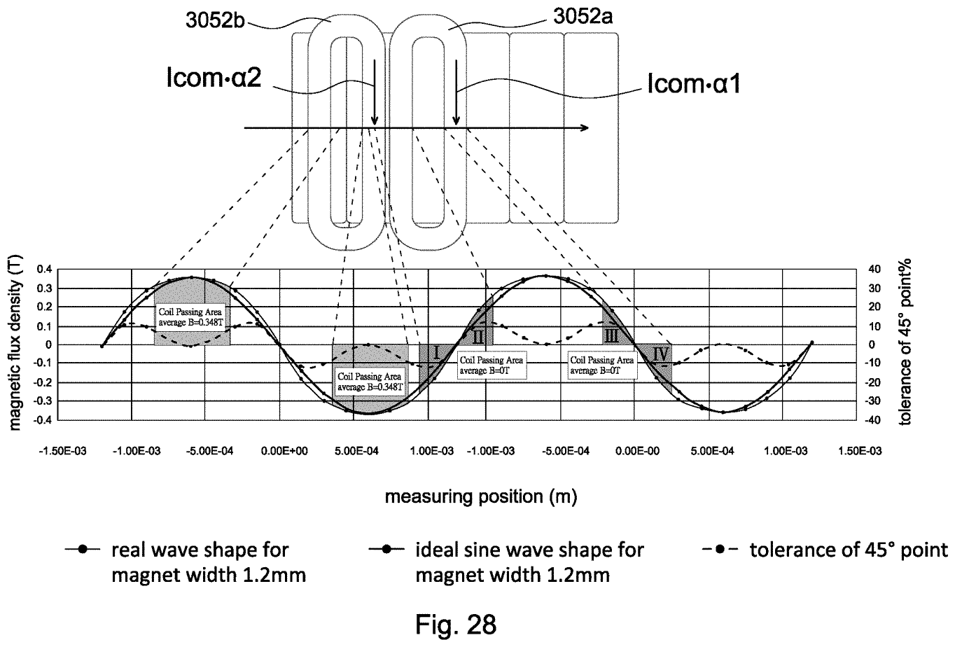

FIG. 28 shows the correlation between the magnetic flux density (T) and the tolerance of 45° point (%) measured in different positions of the magnet during movement of the coil when the magnet width is 1.2 mm, wherein areas I and II can be canceled due to their symmetric shapes and areas III and IV can be also canceled due to their symmetric shapes. Tables 8 and 9 show data for the magnet in different positions. It is worth noting that in Table 9 the maximum of coil-force is 0.248, the minimum of coil-force is 0.237, and the coil-force at the center is 0.2425.

TABLE 8
VCM position 0 · w(m) = 0, (w(m) = 1.2)

| | B (Average) | I (Current) | Force (N/A*) |
|---|---|---|---|
| First coil, Left | 0.348 | 1 | 0.11832 |
| First coil, Right | 0.348 | 1 | 0.11832 |
| Second Coil, Left | 0 | 0 | 0 |
| Second Coil, Right | 0 | 0 | 0 |

TABLE 9
w(m) = 1.2

| Position · | | | | |
|---|---|---|---|---|
| w(m) | First Coil | SecondCoil | Coil-Force(N/A*) | 0.237(N/A*) |
| 0 | 0 | 1 | 0.237 | −2.3 |
| 0.125 | 0.348 | 0.924 | 0.241 | −0.6 |
| 0.25 | 0.707 | 0.707 | 0.248 | 2.3 |
| 0.375 | 0.924 | 0.348 | 0.241 | −0.6 |
| 0.5 | 1 | 0 | 0.237 | −2.3 |
| 0.625 | 0.924 | −0.348 | 0.241 | −0.6 |
| 0.75 | 0.707 | −0.707 | 0.248 | 2.3 |
| 0.875 | 0.348 | −0.924 | 0.241 | −0.6 |
| 1 | 0 | −1 | 0.237 | −2.3 |
| 1.125 | −0.348 | −0.924 | 0.241 | −0.6 |
| 1.25 | −0.707 | −0.707 | 0.248 | 2.3 |
| 1.375 | −0.924 | −0.348 | 0.241 | −0.6 |
| 1.5 | −1 | 0 | 0.237 | −2.3 |
| 1.625 | −0.924 | 0.348 | 0.241 | −0.6 |
| 1.75 | −0.707 | 0.707 | 0.248 | 2.3 |
| 1.875 | −0.348 | 0.924 | 0.241 | −0.6 |
| 2 | 0 | 1 | 0.237 | −2.3 |

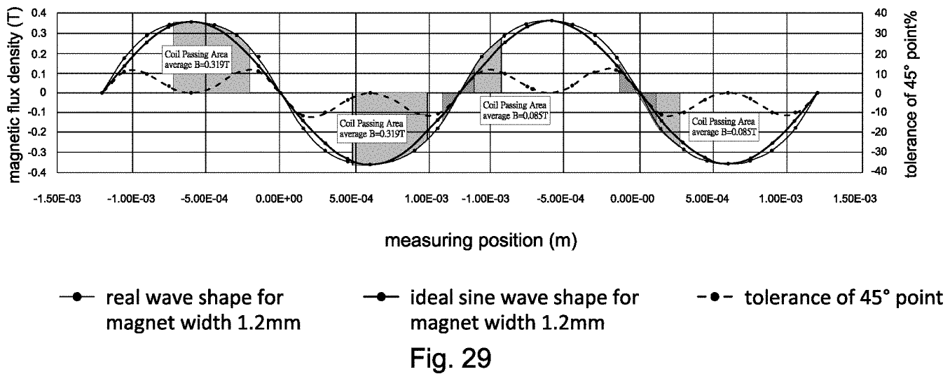

When the coil keeps advancing, the magnetic flux density experienced by the coil in the magnetic field is slightly changed. FIG. 29 shows the correlation between the magnetic flux density (T) and the tolerance of 45° point (%) during movement of the coil. Table 10 correspondingly shows the data for the magnet in different positions.

TABLE 10
VCM position 0.125 · w(m) = 0, (w(m) = 1.2)

| | B (Average) | I (Current) | Force (N/A*) |
|---|---|---|---|
| First coil, Left | 0.348 | 0.924 | 0.109313 |
| First coil, Right | 0.348 | 0.924 | 0.109313 |
| Second Coil, Left | 0.085 | 0.383 | 0.01106 |
| Second Coil, Right | 0.085 | 0.383 | 0.01106 |

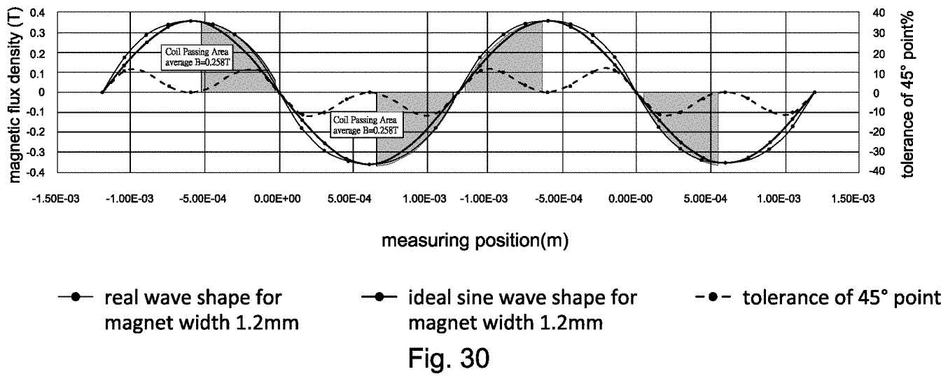

When the coil further keeps advancing, the magnetic flux density experienced by the coil in the magnetic field is changed as shown in FIG. 30. Table 11 correspondingly shows the data for the magnet in different positions.

TABLE 11
VCM position 0.25 · w(m) = 0, (w(m) = 1.2)

| | B (Average) | I (Current) | Force (N/A*) |
|---|---|---|---|
| First coil, Left | 0.258 | 0.707 | 0.062027 |
| First coil, Right | 0.258 | 0.707 | 0.062027 |
| Second Coil, Left | 0.258 | 0.707 | 0.062027 |
| Second Coil, Right | 0.258 | 0.707 | 0.062027 |

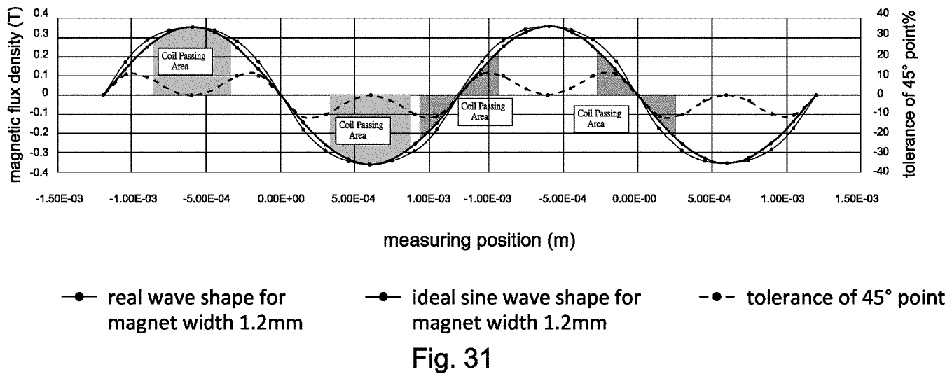

When the coil further keeps advancing, the magnetic flux density experienced by the coil in the magnetic field is changed as shown in FIG. 31.

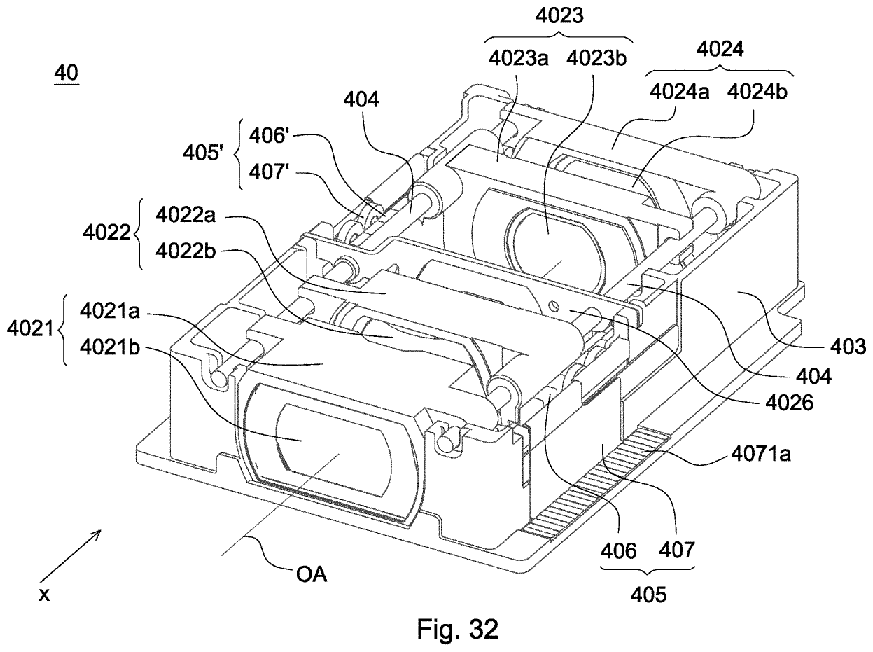

FIG. 32 is a schematic view showing the structure of a lens module 40 in accordance with the third embodiment of the invention. As shown, the lens module 40 of the invention includes a base 403 in which a first lens group 4021, a second lens group 4022, an aperture stop 4026, a third lens group 4023 and a fourth lens group 4024 are sequentially arranged in a first direction X. The first lens group 4021, the second lens group 4022, the third lens group 4023 and the fourth lens group 4024 have an optical axis OA extending in the first direction X, and are supported by a guide unit 404. In this embodiment, the guide unit 404 includes two parallel guide rods. The guide rods are extended in the first direction X and are disposed at two sides of the first lens group 4021, the second lens group 4022, the aperture stop 4026, the third lens group 4023 and the fourth lens group 4024 to provide a support for them. It is understood that the number of the guide rods may be less than or more than two. Further, the guide unit 404 may be replaced with guide rails, guide grooves or other different structures to provide the support.

The first lens group 4021 includes a first lens frame 4021a and one or more first lenses 4021b disposed in the first lens frame 4021. The second lens group 4022 includes a second lens frame 4022a and one or more second lenses 4022b disposed in the second lens frame 4022a. The third lens group 4023 includes a third lens frame 4023a and one or more third lenses 4023b disposed in the third lens frame 4023a. The fourth lens group 4024 includes a fourth lens frame 4024a and one or more fourth lenses 4024b disposed in the fourth lens frame 4024a. In this embodiment, the first lens group 4021 and the fourth lens group 4024 are fixed in the base 403. The second lens group 4022 and the third lens group 4023 are respectively driven by the driving devices 405, 405′ to move in the first direction X. The aperture stop 4026 is fixedly disposed in the base 403 and between the second lens group 4022 and the third lens group 4023.

In this embodiment, the lens module 40 includes four lens groups, wherein the first lens group 4021 and the fourth lens group 4024 are stationary, and the second lens group 4022 and the third lens group 4023 are movable. However, the invention is not limited thereto. The number of the lens groups may be three, five or more. The first lens group 4021 and the fourth lens group 4024 may be movable, and the second lens group 4022 and the third lens group 4023 may be stationary. Alternatively, one of the first lens group 4021 and the fourth lens group 4024 is movable and the other of the first lens group 4021 and the fourth lens group 4024 is stationary, and one of the second lens group 4022 and the third lens group 4023 is movable and the other of the second lens group 4022 and the third lens group 4023 is stationary. In other words, the first lens group 4021, the second lens group 4022, the third lens group 4023 and the fourth lens group 4024 can be selected to be stationary lens group(s) and movable lens group(s) in any combination. Further, the aperture stop 4026 is not limited to be disposed between the second lens group 4022 and the third lens group 4023. For example, the aperture stop 4026 may be disposed between the first lens group 4021 and the fourth lens group 4024. All above changes belong to the category of the invention.

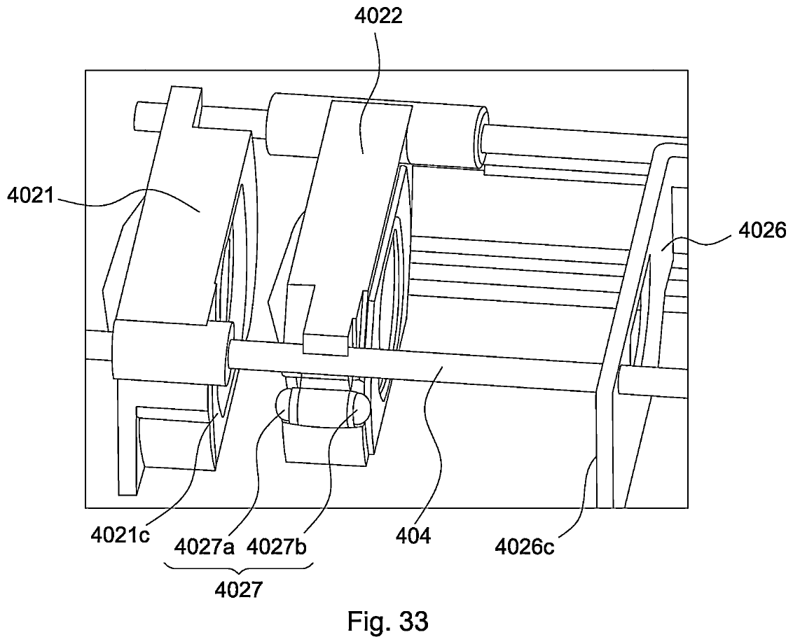

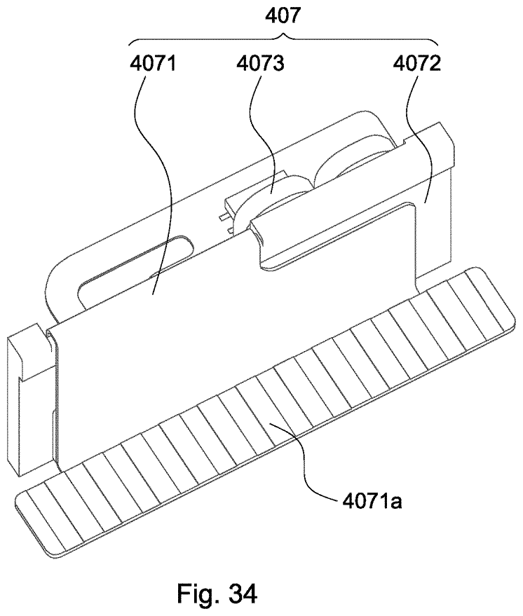

As described above, the first lens group 40021, the aperture stop 4026 and the fourth lens group 4024 are stationary, and the second lens group 4022 and the third lens group 4023 disposed therebetween are movable. When moving, the second lens group 4022 and the third lens group 4023 may come into contact with the first lens group 4021, the aperture stop 4026 or the fourth lens group 4024 to generate noise, scratches or even damage. Further, when the driving devices 405, 405′ are not supplied with power to drive the second lens group 4022 and the third lens group 4023, the second lens group 4022 and the third lens group 4023 are free to slide and may come into contact with the first lens group 4021, the aperture stop 4026 or the fourth lens group 4024 that can also generate noise. The technical scheme of the invention for addressing the issue will be described below by taking the second lens group 4022 as an example with reference to FIG. 33.

Referring to FIG. 33, FIG. 33 is a schematic view showing part of structure of the lens module in accordance with the third embodiment of the invention. As shown, a buffer unit 4027 is provided on a side of the second lens group 4022 to reduce the noise generated by a contact of the second lens group 4022 with the first lens group 4021 or the aperture stop 4026 during movement of the second lens group 4022. The buffer unit 4027 is configured to provide a buffering effect for avoiding damage or scratches caused by collision between the lens groups and the aperture stop, to promote impact resistance and reliability of the lens module, and to avoid scratches that is susceptible to attachment of dust. In detail, the buffer unit 4027 includes a first propping portion 4027a extending towards the first lens group 4021, and a second propping portion 4027b extending towards the aperture stop 4026. That is, the buffer unit 4027 including the first propping portion 4027a and the second propping portion 4027b is extended in the first direction X. The first propping portion 4027a is propped against the first lens group 4021 when the second lens group 4022 moving towards the first lens group 4021 is stopped. The second propping portion 4027b is propped against the aperture stop 4026 when the second lens group 4022 moving towards the aperture stop 4026 is stopped. By the buffer unit 4027 (i.e. the first propping portion 4027a and the second propping portion 4027b) designed to provide the buffering and stopping functions, the damage to the lens groups arising from collision between each other can be avoided, and the noise arising from collision of the lens group with other elements can be reduced. In the invention, the buffer unit 4027 is made of the material that has low strength and good impact absorbing property. The material is, for example, polyoxymethylene (POM) or other material with POM adhered thereto or formed thereon in other ways, to provide buffering and noise-reducing functions.

When the driving device 405 is not supplied with power, the second lens group 4022 is not kept in position and can slide freely. The buffer unit 4027 is able to reduce the noise generated by the collision of the freely-moving second lens group 4022 with the first lens group 4021 or the aperture stop 4026.

Additional buffering material (e.g. liquid silicone rubber) can be applied onto the contact portions 4021c, 4026c of the first lens group 4021 and the aperture stop 4026 where the first lens group 4021 and the aperture stop 4026 contact the buffer unit 4027. After curing, the buffering material is successfully formed on the contact portions 4021c, 4026c of the first lens group 4021 and the aperture stop 4026. By such arrangement, the noise generated by the collision can be effectively reduced due to the property of silicone rubber. Further, silicone rubber has a property of less deformation. When the second lens group 4022 collides with the first lens group 4021 or the aperture stop 4026, the silicone rubber has less deformation. Therefore, the second lens group 4022 is able to stay in a correct position. Further, silicone rubber is less sticky. When the second lens group 4022 separates from the first lens group 4021 or the aperture stop 4026, it will not affect the separation. Therefore, the noise generated by collision can be reduced, and the precision of operation can be guaranteed.

In this embodiment, the buffer unit 4027 is disposed on the second lens group 4022. However, the invention is not limited thereto. In some embodiments, the buffer unit can be disposed on the first lens group 4021, the aperture stop 4026 or even on the base 403 to provide the buffering and noise reducing functions. In some other embodiments, the buffer unit can include a plurality of independent propping portions that are separately disposed on the first lens group 4021, the second lens group 4022, the aperture stop 4026 and/or the base 403 to provide the buffering and noise reducing functions. Further, the above-mentioned silicone rubber can be disposed anywhere corresponding to the buffer unit (e.g. on the first lens group 4021, the second lens group 4022, the aperture stop 4026 and/or the base 403) as long as the second lens group 4022 can contact the silicone rubber when stopped. In this embodiment, the third lens group 4023 has the same structure as the second lens group 4022 to suppress the noise, and therefore the descriptions thereof are omitted.

Referring to FIG. 32 again, the driving device 405 for driving the second lens group 4022 includes a magnet portion 406 and a coil portion 407. The magnet portion 406 is disposed on a side of the second lens frame 4022a of the second lens group 4022. The coil portion 407 is disposed on an inner side surface of the base 403 and corresponding to the magnet portion 406. When the coil portion 407 is supplied with power, a magnetic force is generated and acts on the magnet portion 406 for driving the second lens group 4022 to move in the first direction X.

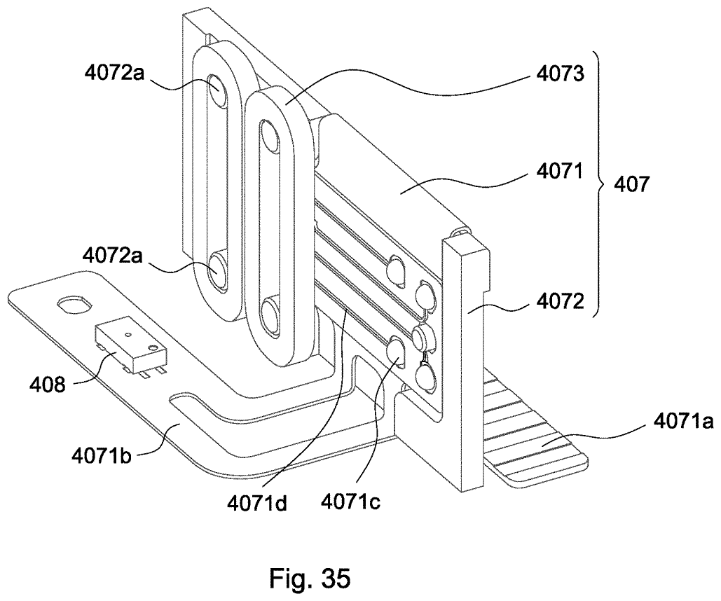

Referring to FIGS. 34 and 35, FIG. 34 is a perspective view of a coil portion 407 in accordance with the third embodiment of the invention, and FIG. 35 is another perspective view of a coil portion 407 observed at different angle in accordance with the third embodiment of the invention. As shown, the coil portion 407 includes a carrier 4072, a flexible circuit board 4071 and plural coils 4073. The carrier 4072 is substantially planar. Plural columnar protrusions 4072a are disposed on the carrier 4072 for fixing the coils 4073. The coils 4073 are fixed to the columnar protrusions 4072a by twining, hanging, gluing or in other fixing ways. The flexible circuit board 4071 is bent and connected to the carrier 4072 and has an electrically connecting portion 4071a extended in a direction (away from the second lens group 4022) and an extending portion 4071b extended in an opposite direction (towards the second lens group 4022). The electrically connecting portion 4071a is electrically connected to an external power supply (not shown) for introducing an electric current. The electric current flows through the bonding pads 4071c formed on the flexible circuit board 4071 and the conducting lines 4071d to the coils 4073, thereby generating a variation of the magnetic field that acts on the magnet portion 406 and drives the second lens group 4022 to move in the first direction X. Further, in the invention, a position sensor (e.g. Hall sensor) 408 is disposed on the extending portion 4071b of the flexible circuit board 4071 for sensing the moving distance or position of the second lens group 4022.

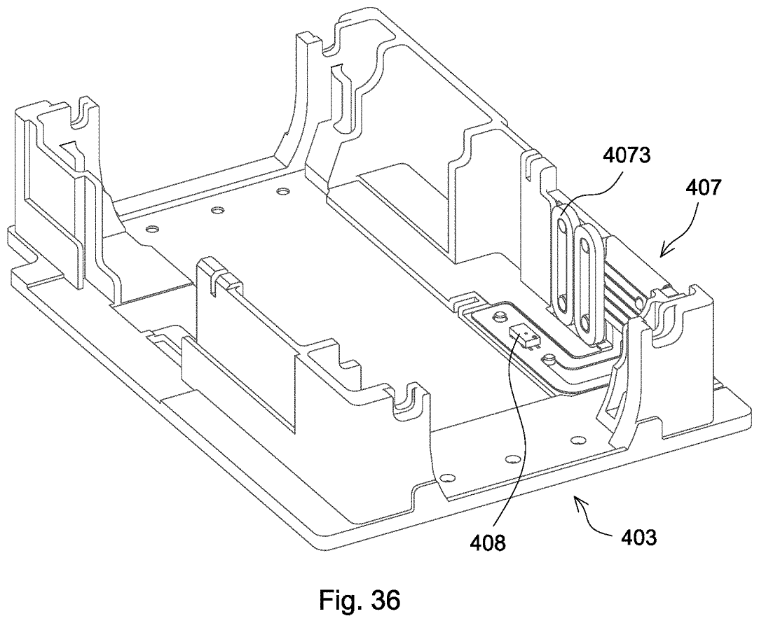

From the above descriptions, it is understood that the flexible circuit board 4071 and the coils 4073 of the invention are modularized into a part (i.e. coil portion 407) in advance, with the position sensor 408 disposed thereon. During the assembly, therefore, the coil portion 407 can be directly installed on the base 403 as shown in FIG. 36. By such arrangement, the positioning of the coils 4073 on the base 403 is simple and convenient. The conventional way of positioning of the coils on the base is avoided so that the efficiency of assembly and the quality of product can be promoted.

Referring to FIG. 32 again, the driving device 405 is provided for driving the second lens group 4022. In the invention, another driving device 405′ is provided for driving the third lens group 4023. The driving device 405′ including a magnet portion 406′ and a coil portion 407′ has the same structure as the driving device 405 including the magnet portion 406 and the coil portion 407 and therefore the descriptions thereof are omitted.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A lens module, comprising:
a base;
a movable lens group which is movable in a first direction and has an optical axis in parallel to the first direction;
a magnet portion disposed on one of the base and the movable lens group;
a coil portion disposed on the other of the base and the movable lens group and corresponding to the magnet portion.

2. The lens module as claimed in claim 1, wherein the coil portion consists of two coils, the magnet portion comprises three magnets arranged in the first direction, the magnets are monopole magnets with N-pole and S-pole alternatively arranged in the first direction.

3. The lens module as claimed in claim 2, further comprising a magnetic substance with the magnets adhered thereto.

4. The lens module as claimed in claim 2, wherein the magnets satisfy at least one of following conditions:
w(p)≥w(m),
w(c)=(1.5+n)w(p),n=0,1,2 . . . ,
w(ec−ec)=w(p),
1.0 mm≤w(m)≤1.35 mm,
where w(p) is a magnet pitch of each of the magnets, w(m) is a width of each of the monopole magnets, w(c) is a distance between centers of the coils, and w(ec−ec) is a distance between centers of winding width of each of the coils.

5. The lens module as claimed in claim 2, wherein the coils comprise a first coil and a second coil, and electric currents applied to the first coil and the second coil satisfy:
$$I\_c1 = Icom \cdot sin ( 360 ° \cdot \frac{P}{2 w ( m )} + θ ) \\ I\_c2 = Icom \cdot sin ( 360 ° \cdot \frac{P}{2 w ( m )} + ( θ + 90 ° ) )$$
where I_c1 is the electric current applied to the first coil, I_c2 is the electric current applied to the second coil, Icom is a common current of the first coil and the second coil, P is a position of the coil portion, and θ is a phase shift amount when P=0.

6. The lens module as claimed in claim 1, wherein the coil portion consists of two coils arranged in the first direction, the magnet portion comprises a multi-pole magnet with N-pole and S-pole alternatively arranged in the first direction.

7. The lens module as claimed in claim 6, wherein the coils comprise a first coil and a second coil, and electric currents applied to the first coil and the second coil satisfy:
$$I\_c1 = Icom \cdot sin ( 360 ° \cdot \frac{P}{2 w ( m )} + θ ) \\ I\_c2 = Icom \cdot sin ( 360 ° \cdot \frac{P}{2 w ( m )} + ( θ + 90 ° ) )$$
where I_c1 is the electric current applied to the first coil, I_c2 is the electric current applied to the second coil, Icom is a common current of the first coil and the second coil, P is a position of the coil portion, and θ is a phase shift amount when P=0.

8. The lens module as claimed in claim 1, further comprising:
a position magnet disposed on the base;
a sensor disposed on the movable lens group to sense a position or a moving distance of the position magnet; and
a driving unit receiving a signal of the position or the moving distance of the position magnet from the sensor and correspondingly adjusting an electric current applied to the coil portion.

9. The lens module as claimed in claim 1, further comprising:
a first lens group which is fixedly disposed in the base; and
a buffer unit disposed in the base;
wherein the movable lens group is a second lens group which is disposed in the base, and the first lens group and the second lens group are arranged along the optical axis;
wherein the buffer unit contacts with the first lens group when the second lens group moving towards the first lens group is stopped.

10. The lens module as claimed in claim 9, wherein the buffer unit is disposed on at least one of the first lens group, the second lens group and the base.

11. The lens module as claimed in claim 9, further comprising an aperture stop disposed in the base;
wherein the buffer unit is disposed on the second lens group and comprises a first propping portion and a second propping portion;
wherein the first propping portion is extended towards the first lens group;
wherein the second propping portion is extended towards the aperture stop;
wherein the first propping portion is propped against the first lens group when the second lens group is moved towards the first lens group and is stopped;
wherein the second propping portion is propped against the aperture stop when the second lens group is moved towards the aperture stop and is stopped.

12. The lens module as claimed in claim 9, wherein material of the buffer unit comprises polyoxymethylene or the buffer unit has polyoxymethylene provided thereon.

13. The lens module as claimed in claim 9, further comprising buffering material;
wherein the buffer material is disposed on the first lens group or the second lens group;
wherein the buffer unit contacts with the buffering material when the second lens group is moved towards the first lens group and is stopped.

14. The lens module as claimed in claim 9, further comprising a driving device for driving the second lens group to move, wherein the driving device comprises a magnet portion disposed on the second lens group and a coil portion disposed in the base and corresponding to the magnet portion.

15. The lens module as claimed in claim 14, wherein the coil portion comprises a plurality of coils and a flexible circuit board, the flexible circuit board supplies power to the coils to generate a magnetic field that acts on the magnet portion, and the second lens group is driven to move along the optical axis when the coil portion is supplied with power to generate a magnetic force that acts on the magnet portion.

16. The lens module as claimed in claim 15, wherein the coil portion further comprises a carrier and a plurality of columnar protrusions, the carrier is substantially planar, the columnar protrusions are disposed on the carrier to fix the coils, and the flexible circuit board is bent and is connected to the carrier.

17. The lens module as claimed in claim 15, further comprising a position sensor;
wherein the magnet portion is disposed on the second lens group;
wherein the coil portion is disposed on the base;
wherein the flexible circuit board comprises an extending portion extended towards the second lens group;
wherein the position sensor is disposed on the extending portion;
wherein the flexible circuit board comprises an electrically connecting portion extended in a direction away from the second lens group and configured to connect to an external power supply.

18. The lens module as claimed in claim 9, further comprising a third lens group, a fourth lens group and an aperture stop, wherein the first lens group and the fourth lens group are fixed, the second lens group and the third lens group are movable, and the aperture stop is fixedly disposed in the base and between the first lens group and the fourth lens group.

19. The lens module as claimed in claim 9, further comprising a third lens group, a fourth lens group and an aperture stop, wherein the first lens group and the fourth lens group are movable, the second lens group and the third lens group are fixed, and the aperture stop is fixedly disposed in the base and between the first lens group and the fourth lens group.

20. The lens module as claimed in claim 9, further comprising a third lens group, a fourth lens group and an aperture stop;
wherein one of the first lens group and the fourth lens group is movable and the other of the first lens group and the fourth lens group is fixed;
wherein one of the second lens group and the third lens group is movable and the other of the second lens group and the third lens group is fixed;
wherein the aperture stop is fixedly disposed in the base and between the first lens group and the fourth lens group.
